(19) United States
(12) Patent Application Publication
(10) Pub. No.: US 2026/0136657 A1
(43) Pub. Date: May 14, 2026

(54) STRUCTURE AND METHOD FOR METAL GATE ISOLATION

(71) Applicant: Taiwan Semiconductor Manufacturing Company, Ltd., Hsinchu (TW)

(72) Inventors: I-Wei Yang, Yilan County (TW); Chao-Hsuan Chen, Hsin-Chu (TW); Shu-Yuan Ku, Zhubei City (TW); Ryan Chia-Jen Chen, Hsinchu (TW)

(73) Assignee: Taiwan Semiconductor Manufacturing Company, Ltd., Hsinchu (TW)

(21) Appl. No.: 18/941,233

(22) Filed: Nov. 8, 2024

(51) Int. Cl. H01L 27/092; H01L 21/3213; H01L 21/8238; H01L 29/06; H01L 29/423; H01L 29/49; H01L 29/775; H01L 29/78; H01L 29/786

(52) U.S. Cl. CPC H10D 84/856; H10D 84/0184; H10D 84/038; H10D 30/43; H10D 30/62; H10D 30/6735; H10D 30/6757; H10D 62/121; H10D 64/661; H10P 50/266

(57) ABSTRACT

A method includes: providing a substrate containing a first plurality of fins of a first polarity type, a second plurality of fins of a second polarity type, and a contiguous gate structure that extends over each of the first plurality of fins and second plurality of fins; and forming a first opening in the contiguous gate structure with a first cut between the first pair of fins of the first polarity type and a second opening in the contiguous gate structure with a second cut between the second pair of fins of the second polarity type via common etching operations; wherein performing the common etching operations includes forming the first opening with a first middle critical dimension (MCD) and the second opening with a second MCD, wherein the first MCD is larger than the second MCD.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a partial top view of a semiconductor device during a stage of fabrication that illustrates isolation cuts that are made to gate structures, in accordance with some embodiments.

FIG. 1B is a partial top view of a semiconductor device during a stage of fabrication that illustrates dense cuts that are made to gate structures, in accordance with some embodiments.

FIG. 1C is a cross-sectional view of a semiconductor device (e.g., semiconductor device 100 or semiconductor device 150) during a stage of fabrication that illustrates cuts (isolation cuts or dense cuts) that are made to gate structures for a FinFET, in accordance with some embodiments.

FIG. 1D is a cross-sectional view of a semiconductor device (e.g., semiconductor device 100 or semiconductor device 150) during a stage of fabrication that illustrates cuts (isolation cuts or dense cuts) that are made to gate structures for a GAAFET, in accordance with some embodiments.

FIG. 2A is a cross sectional view of a semiconductor device during a stage of fabrication that illustrates cuts (isolation cuts or dense cuts) that are made to gate structures for a FinFET, in accordance with some embodiments.

FIG. 2B is a cross sectional view of a semiconductor device during a stage of fabrication that illustrates cuts (isolation cuts or dense cuts) that are made to gate structures for a GAAFET, in accordance with some embodiments.

FIG. 3 is a flow chart depicting an example method of semiconductor fabrication including fabrication of multi-gate devices, in accordance with some embodiments.

FIGS. 4-5, 6A-6C, 7, 8A-8B, and 9-17, are cross-sectional diagrams that illustrate a semiconductor device or structure at various stages of fabrication, in accordance with some embodiments.

FIG. 18 is a flow chart depicting an example cut metal gate process 1800, in accordance with some embodiments.

FIGS. 19A-19H are cross-sectional diagrams that illustrate a semiconductor device or structure at various stages of fabrication, in accordance with some embodiments.

FIG. 20 is a flow diagram depicting an example method of forming a trench in a metal gate, according to some embodiments.

FIG. 21A is a cross-section diagram of an example semiconductor structure with a pair of p-channel fins for a GAAFET and a pair of n-channel fins for a GAAFET formed above a substrate, according to some embodiments.

FIG. 21B is a cross-section diagram of an example semiconductor structure with a pair of p-channel fins for a FinFET and a pair of n-channel fins for a FinFET formed above a substrate, according to some embodiments.

FIG. 22 is a graph of change in ring oscillator speed percentage vs. end cap length, according to some embodiments

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers, and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5° less than or equal to ±4°, less than or equal to ±3°, less than or equal to ±2°, less than or equal to ±1°, less than or equal to ±0.5°, less than or equal to ±0.1°, or less than or equal to ±0.05°.

Gate structures in field effect transistors may extend across two or more transistors. For example, the gate structures may be formed as long “lines” across the active regions of the substrate, such as the fin structures. Once the gate structures are formed, a patterning process “cuts” the long gate structure to shorter sections according to a desired layout. In other words, the patterning process removes portions of the long gate structure and portions of interlayer dielectric (ILD) structure surrounding the long gate structure to form one or more “cuts” and separate the long line into shorter sections. This process may be referred to as a cut-metal-gate (CMG) process. Subsequently, the cuts formed between the separated sections of the long gate structure are filled with a gap fill material, such as a dielectric material of silicon nitride (SiN). Silicon nitride not only electrically isolates adjacent sections of the long gate structure, but also protects the exposed gate structure layers from oxygen diffusion.

A similar process, referred to as cut-dummy-poly (CPO), involves removing portions of a long hybrid or dummy gate structure and portions of interlayer dielectric (ILD) structure surrounding the long hybrid or dummy gate structure to form one or more “cuts” and separate the long line of the hybrid gate structure into shorter sections. Subsequently, the cuts formed between the separated sections of the hybrid gate structure are filled with a gap fill structure, such as a dielectric material of SN. The CPO process may be performed before metal gate (MG) fill, whereas the CMG process may be performed after MG fill. Each process has its own advantages and disadvantages.

In novel technology devices, such as FinFET, NanosheetFET, GAAFET (gate all around FET), and others, isolating a metal gate (MG) through a cut process can become difficult due to a small MG critical dimension (CD) (e.g., shrinking pitch). Embodiments will now be described with respect to particular examples including GAAFET manufacturing processes. Embodiments, however, are not limited to the examples provided herein, and the ideas may be implemented in a wide array of embodiments. The subject matter disclosed herein may be applied to the CPO and the CMG processes.

While the figures illustrate various embodiments of a semiconductor device, additional features may be added in the semiconductor device depicted in the figures and some of the features described below can be replaced, modified, or eliminated in other embodiments of the semiconductor device.

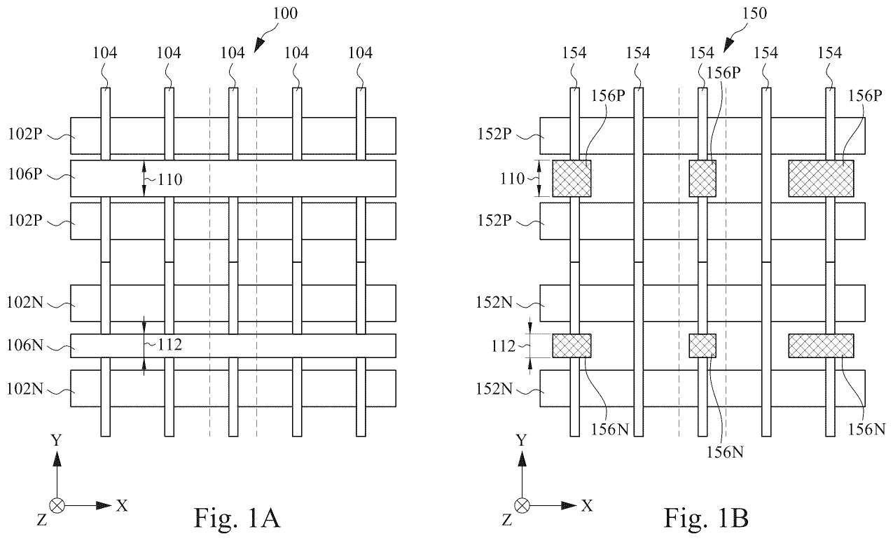

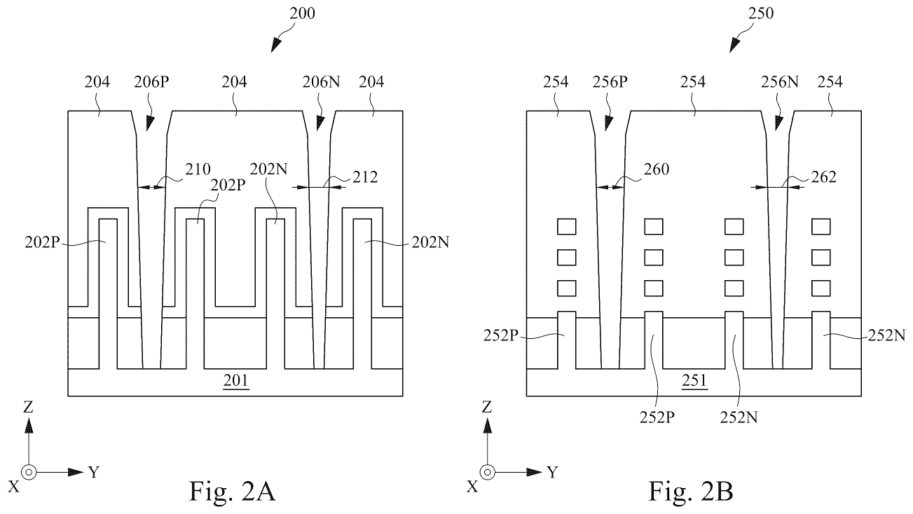

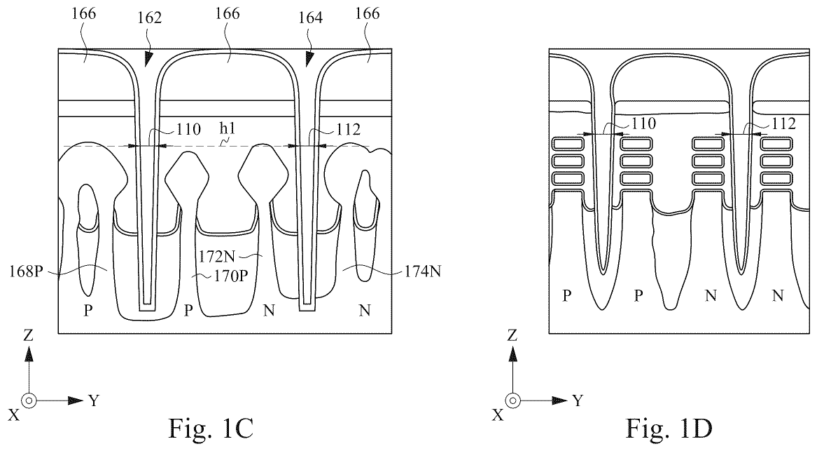

FIG. 1A is a partial top view of a semiconductor device 100 during a stage of fabrication that illustrates isolation cuts that are made to gate structures. The example semiconductor device 100 includes a plurality of fins 102P of a first polarity type (p-type in this example) and a plurality of fins 102N of a second polarity type (n-type in this example) extending laterally in an X-direction. The example semiconductor device 100 further includes a plurality of polysilicon gate structures 104 extending laterally in a Y-direction across the plurality of fins 102P of the first polarity type (e.g., p-type) and the plurality of fins 102N of the second polarity type (e.g., n-type). In this example, the fin to fin pitch is from about 50 to 100 nm and the cut process (CPO or CMG) is considered to provide an isolation cut. Shown are a plurality of isolation cuts 106P, 106N wherein each isolation cut 106P, 106N (e.g., cut LT) comprises a long trench that separates many polysilicon gate structures 104. The isolation cuts 106P are made to gate structures 104 between p-type transistors, and the isolation cuts 106N are made to gate structures 104 between n-type transistors. The isolation cuts 106P and 106N are made using a CMG process recipe that results in P-Metal site CD enlargement (the CD of cut 106P is larger than the CD of cut 106N), a ring oscillator percentage (RO%) boost of approximately 0.5% for p-type transistors formed from p-type fins, avoiding possible metal damage (e.g., to Al metal layers in the metal gate for the n-type transistors), and avoiding Vt shift of the n-type transistors. In various embodiments, the isolation cuts 106P have a middle critical dimension (MCD 110) of about 21.5 nm and the isolation cuts 106N have a middle critical dimension (MCD 112) of about 18 nm while both the cuts 106P and 106N are made using the same CMG process recipe. In various embodiments, the MCD 110 of trenches formed by cuts between p-type transistors is approximately 1.15 times to approximately 1.2 times (e.g., greater than 10%) larger than the MCD 112 of trenches formed by cuts between n-type transistors. In various embodiments, the width of the fins 102P, 102N are about 2 to 50 nm (Fin CD) and the length of the fins 102P, 102N are about 2 to 500 nm (Gate CD).

FIG. 1B is a partial top view of a semiconductor device 150 during a stage of fabrication that illustrates dense cuts that are made to gate structures. The example semiconductor device 150 includes a plurality of fins 152P of a first polarity type (p-type in this example) and a plurality of fins 152N of a second polarity type (n-type in this example) extending laterally in an X-direction. The example semiconductor device 150 further includes a plurality of polysilicon gate structures 154 extending laterally in a Y-direction across the plurality of fins 152P of the first polarity type (e.g., p-type) and the plurality of fins 152N of the second polarity type (e.g., n-type). In this example, the fin to fin pitch is from about 50 to 100 nm and the cut process (CPO or CMG) is considered to provide a dense cut. Shown are a plurality of dense cuts 156P, 156N wherein each dense cut 156P, 156N comprises a short trench that separates a limited number of polysilicon gate structures 154. The dense cuts 156P are made to gate structures 154 between p-type transistors, and the dense cuts 156N are made to gate structures 154 between n-type transistors. The dense cuts 156P and 156N are made using a CMG process recipe that results in P-Metal site CD enlargement (the CD of cut 156P is larger than the CD of cut 156N), a ring oscillator percentage (RO%) boost of approximately 0.5% for p-type transistors formed from p-type fins, avoiding possible metal damage (e.g., to Al metal layers in the metal gate for the n-type transistors), and avoiding Vt shift of the n-type transistors. In various embodiments, the MCD 110 of trenches formed by cuts between p-type transistors is approximately 1.15 times to approximately 1.2 times (e.g., greater than 10%) larger than the MCD 112 of trenches formed by cuts between n-type transistors. In various embodiments, the dense cuts 156P have an MCD 110 of about 21.5 nm and the dense cuts 156N have an MCD 112 of about 18 nm while both the dense cuts 156P and 156N are made using the same CMG process recipe. In various embodiments, the width of the fins 152P, 152N are about 2 to 50 nm (Fin CD) and the length of the fins 152P, 152N are about 2 to 500 nm (Gate CD).

The MCD 110 is a measurement of the thickness of an isolation cut 106P or a dense cut 156P measured at a vertical height at a top surface of the fins of two p-channel transistors between which the isolation cut 106P or dense cut 156P was made. Similarly, the MCD 112 is a measurement of the thickness of an isolation cut 106N or dense cut 156N measured at a vertical height h1 at a top surface of the fins of two n-channel transistors between which the isolation cut 106N or dense cut 156N made. FIGS. 1C and 1D illustrate example measurements of MCD 110 and MCD 112. FIG. 1C is a cross-sectional view of a semiconductor device (e.g., semiconductor device 100 or semiconductor device 150) during a stage of fabrication that illustrates cuts (isolation cuts or dense cuts) that are made to gate structures for a FinFET. FIG. 1D is a cross-sectional view of a semiconductor device (e.g., semiconductor device 100 or semiconductor device 150) during a stage of fabrication that illustrates cuts (isolation cuts or dense cuts) that are made to gate structures for a GAAFET.

In the example of FIG. 1C, a first cut 162 (e.g., isolation cut 106P or dense cut 156P) was made in the gate structure 166 between a first p-channel transistor 168P and a second p-channel transistor 170P. The cut 162 has an MCD 110 measured at a vertical height h1 at a top surface of the fins of the two p-channel transistors 168P, 170P between which the first cut 162 was made.

In the example of FIG. 1D, a second cut 164 (e.g., isolation cut 106P or dense cut 156P) was made in the gate structure 166 between a first n-channel transistor 172N and a second n-channel transistor 174N. The cut 164 has an MCD 112 measured at the vertical height h1 at a top surface of the fins of the two n-channel transistors 172N, 174N between which the second cut 164 was made.

FIG. 2A is a cross-sectional view of a semiconductor device 200 (e.g., semiconductor device 100 or semiconductor device 150) during a stage of fabrication that illustrates cuts (isolation cuts or dense cuts) that are made to gate structures for a FinFET. The example semiconductor device 200 includes a plurality of fins 202P of a first polarity type (p-type in this example) for FinFET transistors extending vertically in a Z-direction from a substrate 201 and a plurality of fins 202N of a second polarity type (n-type in this example) for FinFET transistors extending vertically in a Z-direction from the substrate 201. The example semiconductor device 200 further include a polysilicon gate structure 204 extending laterally in a Y-direction across the plurality of fins 202P of the first polarity type (e.g., p-type) and the plurality of fins 202N of the second polarity type (e.g., n-type). The example semiconductor device 200 further includes a first cut 206P and a second cut 206N. The first cut 206P may be an isolation cut or a dense cut, and the second cut 206N may be an isolation cut or a dense cut. The first cut 206P is made to gate structure 204 between p-type transistors, and the second cut 206N is made to gate structure 204 between n-type transistors. The first cut 206P and the second cut 206N are made using a CMG process recipe that results in P-Metal site CD enlargement (the CD of cut 206P is larger than the CD of cut 206N), a ring oscillator percentage (RO%) boost of approximately 0.5% for the p-type transistors formed from p-type fins, avoiding possible metal damage (e.g., to Al metal layers in the metal gate for the n-type transistors), and avoiding Vt shift of the n-type transistors. In various embodiments, the first cut 206P has a MCD 210 of about 21.5 nm and the second cuts 206N has a MCD 212 of about 18 nm while both the first cut 206P and the second cut 206N are made using the same CMG process recipe. In various embodiments, the MCD 210 of trenches formed by cuts between p-type transistors is approximately 1.15 times to approximately 1.2 times (e.g., greater than 10%) larger than the MCD 212 of trenches formed by cuts between n-type transistors.

FIG. 2B is a cross sectional view of a semiconductor device 250 (e.g., semiconductor device 100 or semiconductor device 150) during a stage of fabrication that illustrates cuts (isolation cuts or dense cuts) that are made to gate structures for GAAFETs. The example semiconductor device 250 includes a plurality of fins 252P of a first polarity type (p-type in this example) for GAAFETs extending vertically in a Z-direction from a substrate 251 and a plurality of fins 252N of a second polarity type (n-type in this example) for GAAFETs extending vertically in a Z-direction from the substrate 251. The example semiconductor device 250 further include a polysilicon gate structure 254 extending laterally in a Y-direction across the plurality of fins 252P of the first polarity type (e.g., p-type) and the plurality of fins 252N of the second polarity type (e.g., n-type). The example semiconductor device 250 further includes a first cut 256P and a second cut 256N. The first cut 256P may be an isolation cut or a dense cut, and the second cut may be an isolation cut or a dense cut. The first cut 256P is made to gate structure 254 between p-type transistors, and the second cut 256N is made to gate structure 254 between n-type transistors. The first cuts 256P and the second cut 256N are made using a CMG process recipe that results in P-Metal site CD enlargement (the CD of cut 256P is larger than the CD of cut 256N), a ring oscillator percentage (RO%) boost of approximately 0.5% for the p-type transistors formed from p-type fins, avoiding possible metal damage (e.g., to Al metal layers in the metal gate for the n-type transistors), and avoiding Vt shift of the n-type transistors. In various embodiments, the first cut 256P has a MCD of about 21.5 nm and the second cuts 256N has a MCD of about 18 nm while both the first cut 256P and the second cut 256N are made using the same CMG process recipe. In various embodiments, the MCD 260 of trenches formed by cuts between p-type transistors is approximately 1.15 times to approximately 1.2 times (e.g., greater than 10%) larger than the MCD 262 of trenches formed by cuts between n-type transistors.

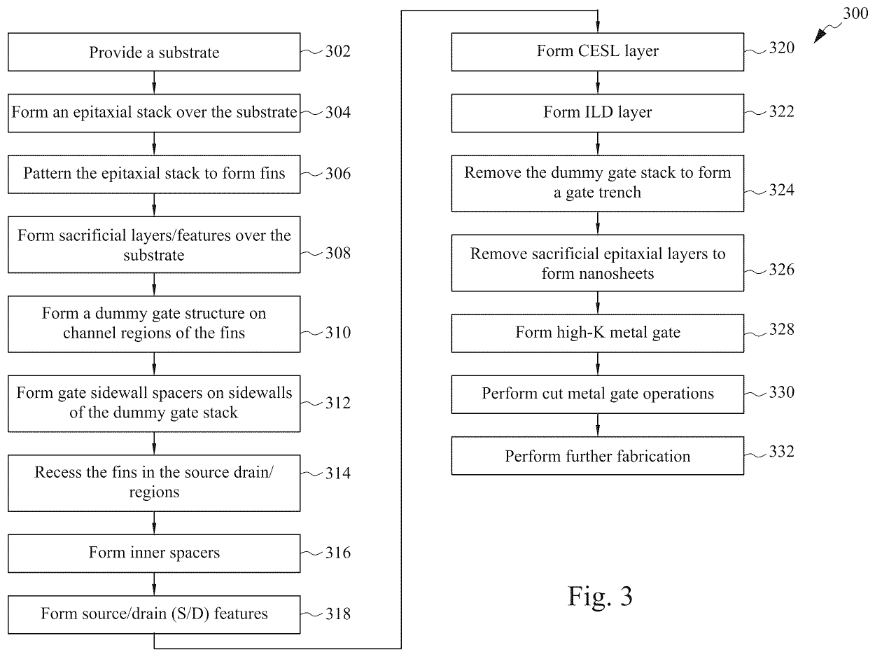

FIG. 3 is a flow chart depicting an example method 300 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAAFET device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

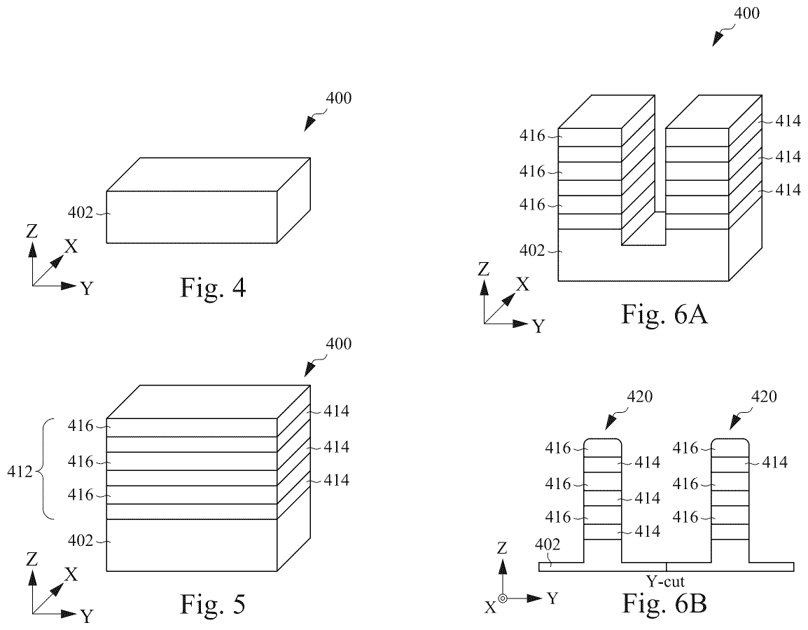

FIG. 3 is described in conjunction with FIGS. 4-5, 6A-6C, 7, 8A-8B, and 9-17, which illustrate a semiconductor device 400 or structure at various stages of fabrication in accordance with some embodiments. The method 300 is merely an example and is not intended to limit the present disclosure beyond what is explicitly recited in the claims. Additional steps may be provided before, during, and after method 300, and some of the steps described can be moved, replaced, or eliminated for additional embodiments of method 300. Additional features may be added in the semiconductor device 400 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 300, include any descriptions given with reference to the figures, as with the remainder of the method and exemplary figures provided in this disclosure, are merely exemplary and are not intended to be limiting beyond what is specifically recited in the claims that follow.

FIGS. 4-5, 6A-6C, 7, 8A-8B, and 9-17, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 302, the example method 300 includes providing a substrate. Referring to the example of FIG. 4, in an embodiment of block 302, a substrate 402 is provided for forming the semiconductor device 400. In some embodiments, the substrate 402 may be a semiconductor substrate such as a silicon (Si) substrate. In some embodiments, the substrate 402 includes a single crystalline semiconductor layer on at least its surface portion. The substrate 402 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 402 may include a compound semiconductor and/or an alloy semiconductor. The substrate 402 may include various layers, including conductive or insulating layers formed on a semiconductor substrate. The substrate 402 may include various doping configurations depending on design requirements. For example, different doping profiles (e.g., n wells, p wells) may be formed on the substrate 402 in regions designed for different device types (e.g., n-type field effect transistors (NFET), p-type field effect transistors (PFET)). The suitable doping may include ion implantation of dopants and/or diffusion processes. The substrate 402 has isolation features (e.g., shallow trench isolation (STI) features) interposing the regions providing different device types. Further, the substrate 402 may be strained for performance enhancement, may include a silicon-on-insulator (SOI) structure, and/or have other suitable enhancement features.

At block 304, the example method 300 then includes forming an epitaxial stack over the substrate that includes a plurality of epitaxial layers. Referring to the example of FIG. 5, in an embodiment of block 304, an epitaxial stack 412 is formed over the substrate 402. The epitaxial stack 412 includes sacrificial epitaxial layers 414 of a first composition interposed by channel epitaxial layers 416 of a second composition. The first and second composition can be different. In an embodiment, the sacrificial epitaxial layers 414 are formed from SiGe and the channel epitaxial layers 416 are formed from silicon (Si). However, other embodiments are possible including those that provide for a first composition and a second composition having different oxidation rates and/or etch selectivity. In some embodiments, the sacrificial epitaxial layer 414 includes SiGe and the channel epitaxial layer 416 includes silicon (Si). However, other embodiments are possible including those that provide for a first composition and a second composition having different oxidation rates and/or etch selectivity. In some embodiments, the sacrificial epitaxial layer 414 includes SiGe and where the channel epitaxial layer 416 includes Si, the Si oxidation rate of the channel epitaxial layer 416 is less than the SiGe oxidation rate of the sacrificial epitaxial layer 414. It is noted that three (3) layers each of epitaxial layers 414 and 416 are illustrated in FIG. 3, which is for illustrative purposes only and not intended to be limiting beyond what is specifically recited in the claims. In various embodiments, any number of epitaxial layers can be formed in the epitaxial stack 412; the number of layers depending on the desired number of channel regions for the device 400. In some embodiments, the number of channel epitaxial layers 416 is between 2 and 10, such as 3, 4 or 5.

In some embodiments, the sacrificial epitaxial layer 414 has a thickness ranging from about 4 nm to about 12 nm. The sacrificial epitaxial layers 414 may be substantially uniform in thickness. In some embodiments, the channel epitaxial layer 416 has a thickness ranging from about 3 nm to about 6 nm. In some embodiments, the channel epitaxial layers 416 of the stack are substantially uniform in thickness.

As described in more detail below, the channel epitaxial layer 416 may serve as channel region(s) for a subsequently formed multi-gate device and its thickness is chosen based on device performance considerations. The sacrificial epitaxial layer 414 may serve to reserve a spacing (or referred to as a gap) between adjacent channel region(s) for a subsequently formed multi-gate device and its thickness is chosen based on device performance considerations.

By way of example, epitaxial growth of the epitaxial stack 412 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 416, include the same material as the substrate 402, such as silicon (Si). In some embodiments, the epitaxially grown layers 414 and 416 include a different material than the substrate 402. As stated above, in at least some examples, the sacrificial epitaxial layer 414 includes an epitaxially grown Si₁₋ₓGex layer (e.g., x is about 25^{˜}55%) and the channel epitaxial layer 416 includes an epitaxially grown Si layer. Alternatively, in some embodiments, either of the sacrificial epitaxial layers 414 and channel epitaxial layers 416 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 414 and channel epitaxial layers 416 may be chosen based on providing differing oxidation and etch selectivity properties. In various embodiments, the epitaxial layers 414 and 416 are substantially dopant-free (i.e., having an extrinsic dopant concentration from about 0 cm⁻³ to about 1×1017 cm⁻³), where for example, no intentional doping is performed during the epitaxial growth process.

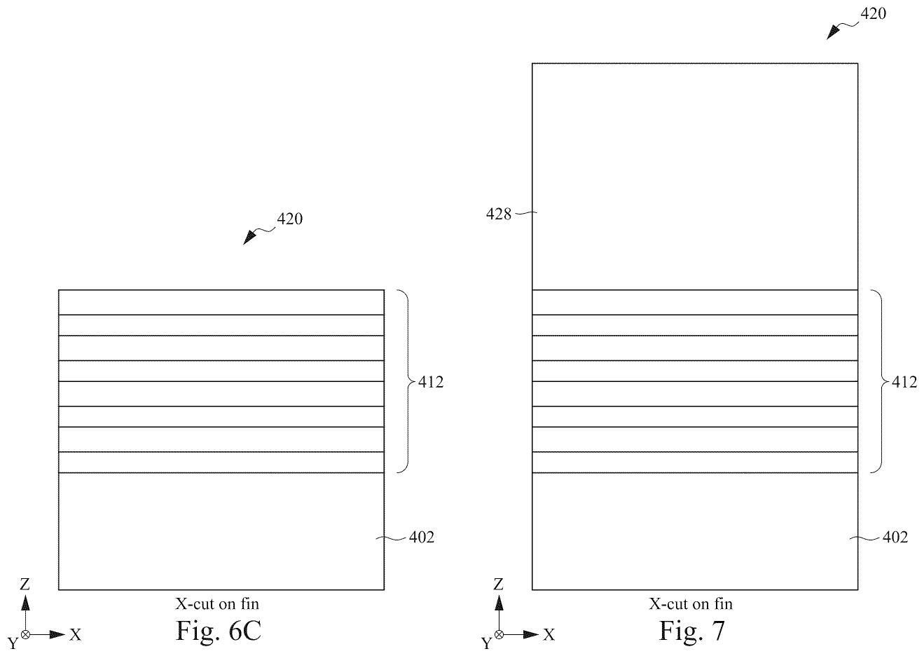

At block 306, the example method 300 includes patterning the epitaxial stack to form semiconductor fins (also referred to as fins). Referring to the example of FIGS. 6A, 6B, and 6C, in an embodiment of block 306, a plurality of fins 420 extending from the substrate 402 are formed. In various embodiments, each of the fins 420 includes an upper portion of the interleaved epitaxial layers 414 and 416 and a bottom portion protruding from the substrate 402.

The fins 420 may be fabricated using suitable processes including photolithography and etch processes. The photolithography process may include forming a photoresist layer over the substrate 402 (e.g., over the epitaxial stack 412), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 402, and epitaxial stack 412 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 308, the example method 300 includes forming one or more sacrificial layers/features over the substrate. Referring to the example of FIG. 7, in an embodiment of block 308, a sacrificial gate dielectric layer (not shown) is blanket deposited over the fin 420, which is formed over the substrate 402. A sacrificial gate electrode layer 428 is then blanket deposited on the sacrificial gate dielectric layer and over the substrate 402. The sacrificial gate electrode layer 428 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 428 may be deposited using CVD, including LPCVD and PECVD, PVD, ALD, or other suitable processes.

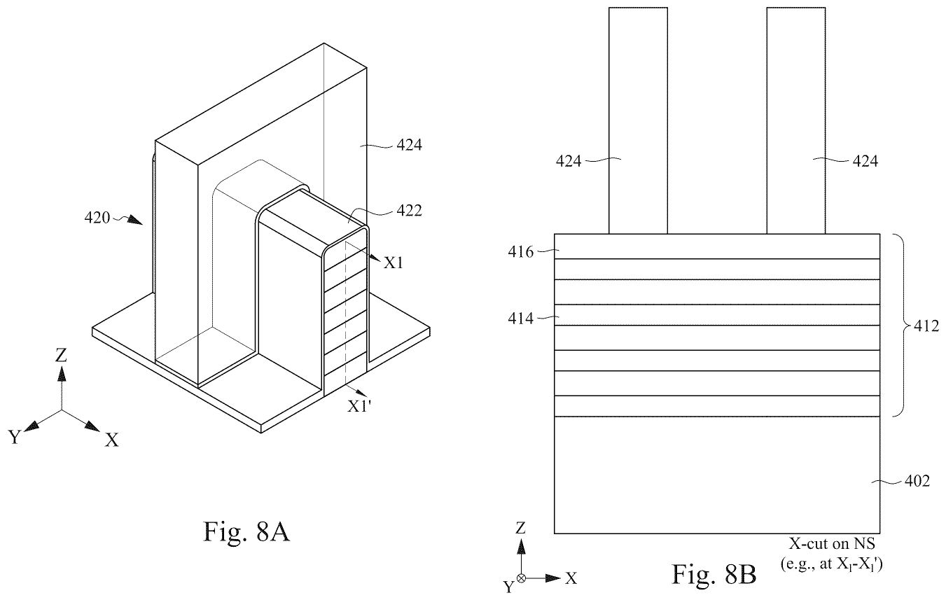

At block 310, the example method 300 includes patterning the one or more sacrificial layers/features to form a dummy gate structure on channel regions of the fins. Referring to the example of FIGS. 8A and 8B, in an embodiment of block 310, a sacrificial gate structure 424 is formed over portions of the fins 420 which are to be channel regions. The sacrificial gate structure 424 defines the channel regions of a GAAFET device. The sacrificial gate structure 424 includes a sacrificial gate dielectric layer and a sacrificial gate electrode layer 428. The sacrificial gate structure 424 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 424. By patterning the sacrificial gate structure 424, the fins 420 are partially exposed on opposite sides of the sacrificial gate structure 424, thereby defining source/drain (S/D) regions. In this disclosure, a source and a drain are interchangeably used, and the structures thereof are substantially the same.

The sacrificial gate structure 424 is subsequently removed as discussed with reference to block 324 of the method 300 and will be replaced by a final gate stack at a subsequent processing stage of the device 400. In particular, the sacrificial gate structure 424 is replaced at a later processing stage by a high-K dielectric layer (HK) and metal gate electrode (MG) as discussed below.

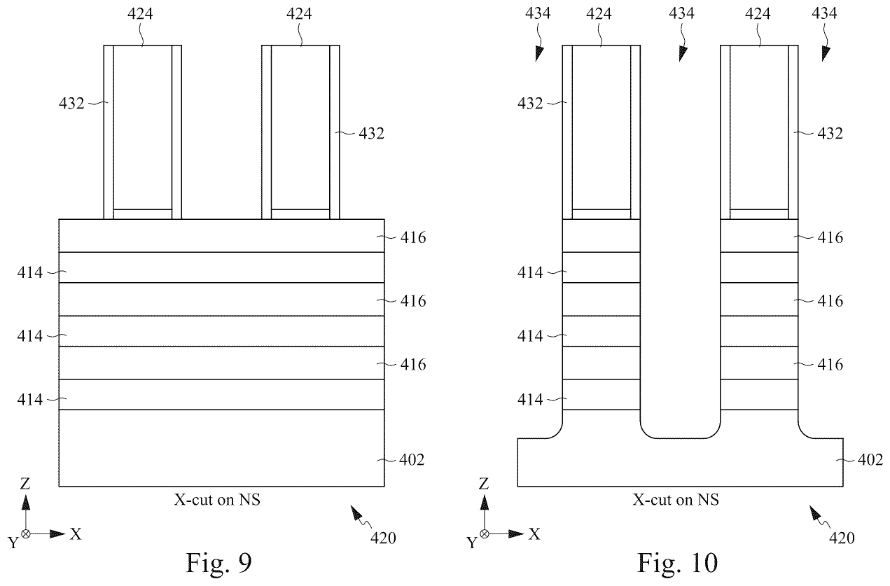

At block 312, the example method 300 includes forming gate sidewall spacers on sidewalls of the sacrificial gate structure. Referring to the example of FIG. 9, in an embodiment of block 312, gate sidewall spacers 432 are formed on sidewalls of the sacrificial gate structure 424. In various embodiments, the gate sidewall spacers 432 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 432 include multiple layers, such as main spacer walls, liner layers, and the like. By way of example, the gate sidewall spacers 432 may be formed by depositing a dielectric material layer over the sacrificial gate structure 424 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 420 adjacent to and not covered by the sacrificial gate structure 424 (e.g., S/D regions). The dielectric material layer may remain on the sidewalls of the sacrificial gate structure 424 as gate sidewall spacers 432. In some embodiments, the etching-back process may include a wet etch process, a dry etch process, a multiple-step etch process, and/or a combination thereof. The gate sidewall spacers 432 may have a thickness ranging from about 5 nm to about 20 nm.

At block 314, the example method includes recessing the fins in the source drain/regions. Referring to the example of FIG. 10, in an embodiment of block 314, the fin 420 is recessed in the source drain/regions. The stacked epitaxial layers 414 and 416 are etched down at the S/D regions to form a recess 434. In various embodiments, the recessing is performed by a suitable etching process, such as a dry etching process, a wet etching process, or an RIE process. Dry etching may be implemented using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof.

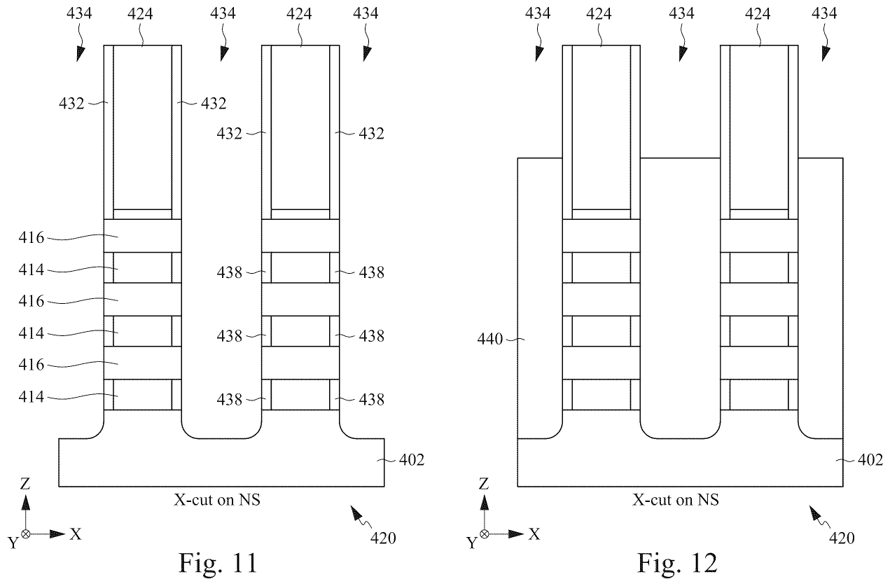

At block 316, the example method 300 Includes forming inner spacers. Forming inner spacers may include recessing sacrificial epitaxial layers (e.g., SiGe), depositing inner spacer material, and etching back inner spacer material. Referring to the example of FIG. 11, in an embodiment of block 316, inner spacers 438 are formed. The sacrificial epitaxial layers 414 have been etched back. The sacrificial epitaxial layers 414 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 318 lateral ends of the sacrificial epitaxial layers 414 that are exposed in the recess 434 may be selectively oxidized to increase the etch selectivity between the epitaxial layers 414 and 416. In some examples, the oxidation process may be performed by exposing the device 400 to a wet oxidation process, a dry oxidation process, or a combination thereof.

The inner spacers 438 may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer can be formed by ALD or any other suitable method. After the inner spacer material layer is formed, an etching operation may be performed to partially remove the inner spacer material layer. In various embodiments, the inner spacers 438 are formed form the same material as the gate sidewall spacers 432. In various embodiments, the gate sidewall spacers 432 and the inner spacers 438 are formed from SiOCN.

At block 318, the example method 300 includes forming source/drain (S/D) features. Referring to the example of FIG. 12, in an embodiment of block 318, epitaxial S/D features 440 are formed in recess 434. In some embodiments, the epitaxial S/D features 440 include silicon for NFETs and SiGe for PFETs. In some embodiments, the epitaxial S/D features 440 are formed by an epitaxial growth method using CVD, ALD, or molecular beam epitaxy (MBE). The epitaxial S/D features 440 are formed in contact with the channel epitaxial layers 416 and separated from the sacrificial epitaxial layers 414 by the inner spacers 438.

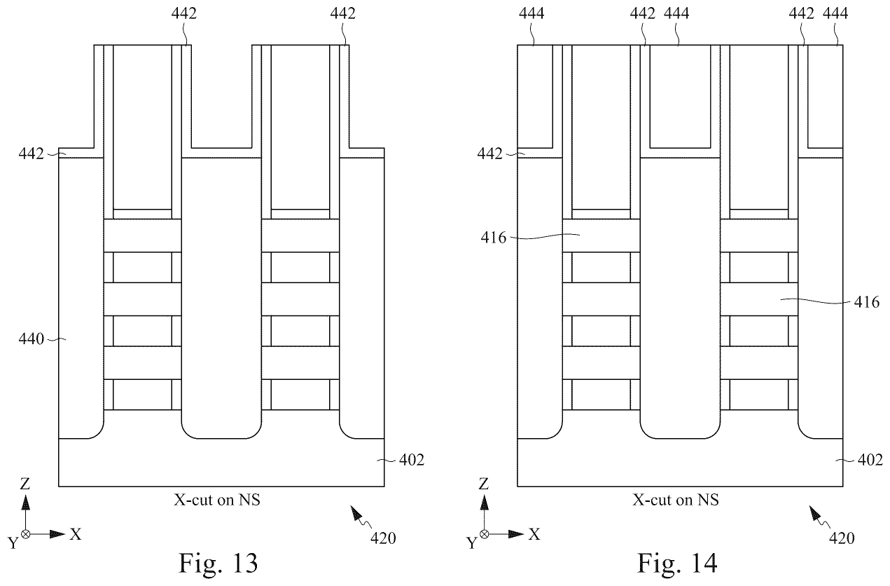

At block 320, the example method 300 includes forming a CESL layer. Referring to the example of FIG. 13, in an embodiment of block 320, a CESL layer 442 is formed over the S/D features 440. The CESL layer 442 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 442 is formed from SiN.

At block 322, the example method 300 includes forming an ILD layer. Referring to the example of FIG. 14, in an embodiment of block 322, an interlayer dielectric (ILD) layer 444 is formed over the CESL layer 442. The ILD layer 444 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 444 may be formed by PECVD, flowable CVD (FCVD), or other suitable methods. In some embodiments, forming the ILD layer 444 further includes performing a CMP process to planarize a top surface of the device 400, such that the top surfaces of the sacrificial gate structure 424 are exposed.

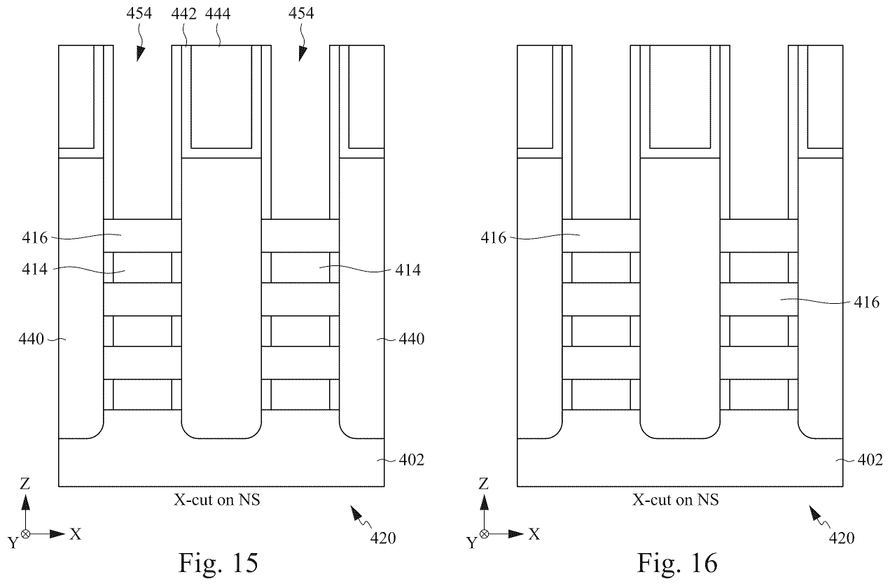

At block 324, the example method 300 includes removing the dummy gate stack to form a gate trench. Referring to the example of FIG. 15, in an embodiment of block 324, the sacrificial gate structure 424 has been removed to form a gate trench 454. The gate trench 454 exposes the fin 420 in the channel region(s). The ILD layer 444 and the CESL layer 442 protects the epitaxial S/D features 440 during the removal of the sacrificial gate structure 424. The sacrificial gate structure 424 can be removed using plasma dry etching and/or wet etching. When the sacrificial gate electrode layer is polysilicon and the ILD layer 444 is an oxide, a wet etchant such as a TMAH solution can be used to selectively remove the sacrificial gate electrode layer. The sacrificial gate dielectric layer is thereafter removed using plasma dry etching and/or wet etching.

At block 326, the example method 300 includes removing the sacrificial epitaxial layers to form nanosheets. Referring to the example of FIG. 16, in an embodiment of block 326, sacrificial epitaxial layers 414 have been removed thereby releasing channel members from the channel region of the GAAFET device. In the illustrated embodiment, channel members are channel epitaxial layers 416 in the form of nanosheets. In various embodiments, the channel epitaxial layers 416 include silicon, and the sacrificial epitaxial layers 414 include silicon germanium. In various embodiments, the plurality of sacrificial epitaxial layers 414 were selectively removed via a selective removal process that included oxidizing the plurality of sacrificial epitaxial layers 414 using a suitable oxidizer, such as ozone. Thereafter, the oxidized sacrificial epitaxial layers 414 were selectively removed via a dry etching process, for example, by applying an HCl gas at a temperature of about 500 degrees Celsius to about 700 degrees Celsius, or applying a gas mixture of CF₄, SF₆, and CHF₃.

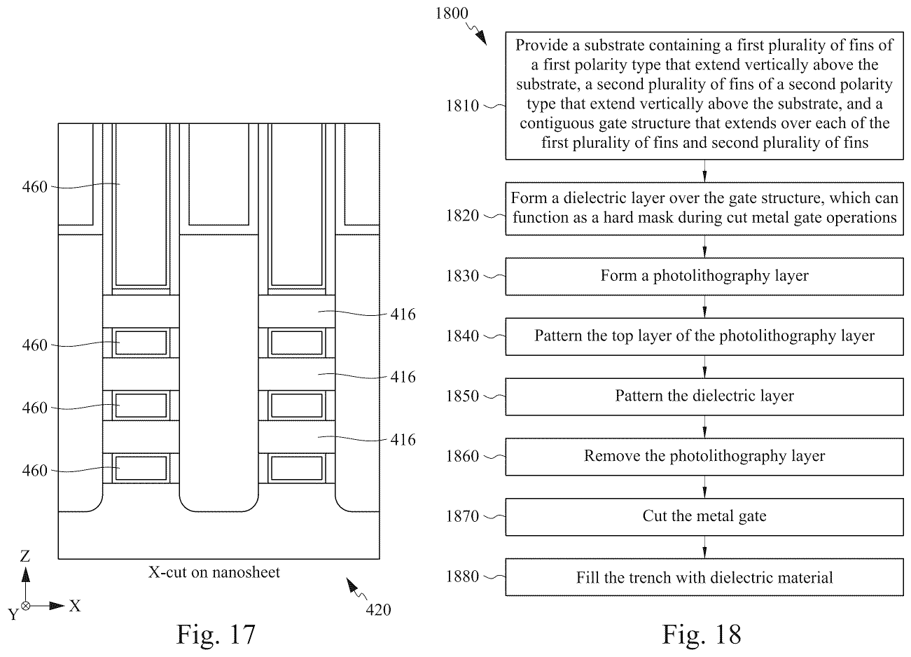

At block 328, the example method 300 includes forming high-K metal gate structures. Referring to the example of FIG. 17, in an embodiment of block 328, a gate structure 460 is formed. In various embodiments, the gate structure is the gate of a multi-gate transistor. In various embodiments, the gate structure is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 416, and the interfacial layer is interposed between the high-k dielectric layer and the nanosheets 416. The interfacial layer may include a dielectric material such as silicon oxide (SiO2) or silicon oxynitride (SiON), and may be formed by chemical oxidation, thermal oxidation, atomic layer deposition (ALD), CVD, and/or other suitable methods. The high-k dielectric layer may include hafnium oxide (HfO2), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO2—Al2O3) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

At block 330, the example method 300 includes performing cut metal gate operations to isolate gate structures for various transistors. In various embodiments, the cut metal gate operations may result in one or more dense cuts and/or isolation cuts. In various embodiments, a first cut is made to a gate structure 460 between p-type transistors and a second cut is made to gate structures 460 between n-type transistors. In various embodiments, the first cut and the second cut are made using a CMG process recipe that results in P-Metal site CD enlargement (with the CD of the first cut larger than the CD of second cut), a ring oscillator percentage (RO%) boost of approximately 0.5% for the p-type transistors formed from p-type fins, avoiding possible metal damage (e.g., to Al metal layers in the metal gate for the n-type transistors), and avoiding Vt shift of the n-type transistors. In various embodiments, the first cut has a MCD of about 21.5 nm and the second cut has a MCD of about 18 nm while both the first cut and the second cut are made using the same CMG process recipe.

At block 332, the example method 300 includes performing further fabrication. A semiconductor device may undergo further processing to form various features and regions known in the art. For example, subsequent processing may form contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 300, and some process steps described above may be replaced or eliminated in accordance with various embodiments of the method 300.

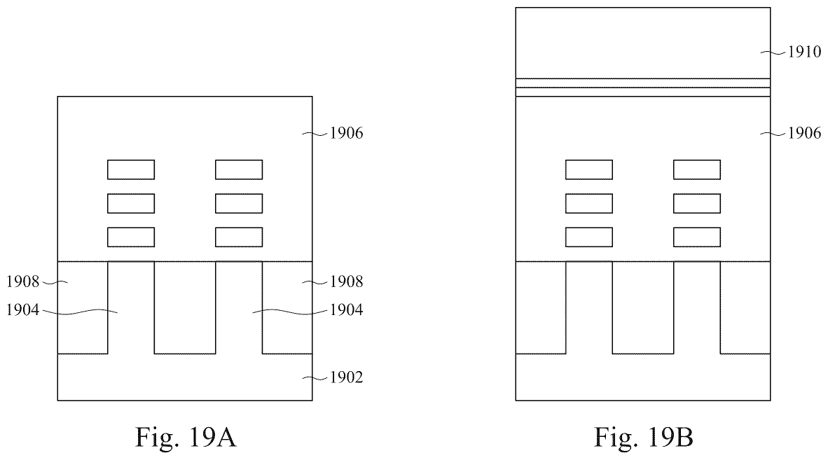

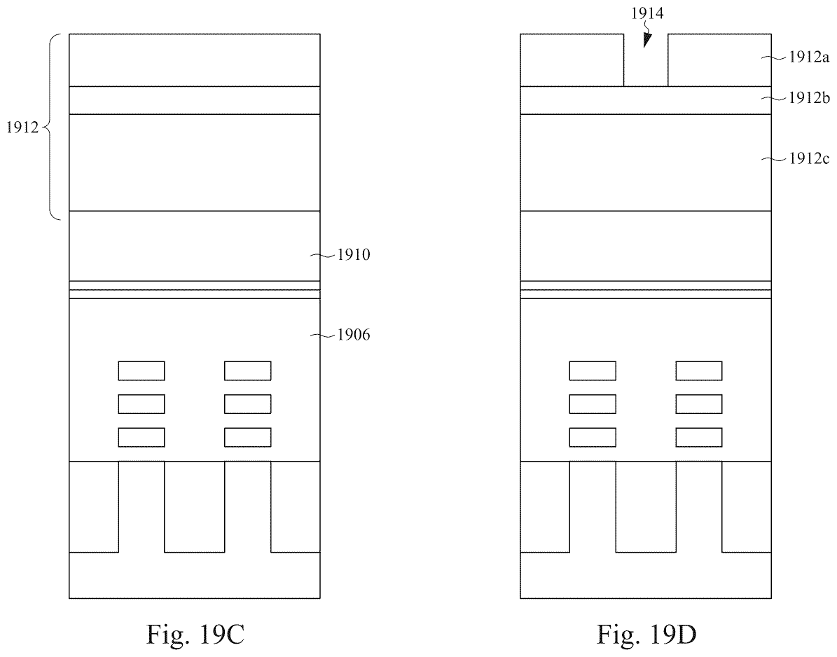

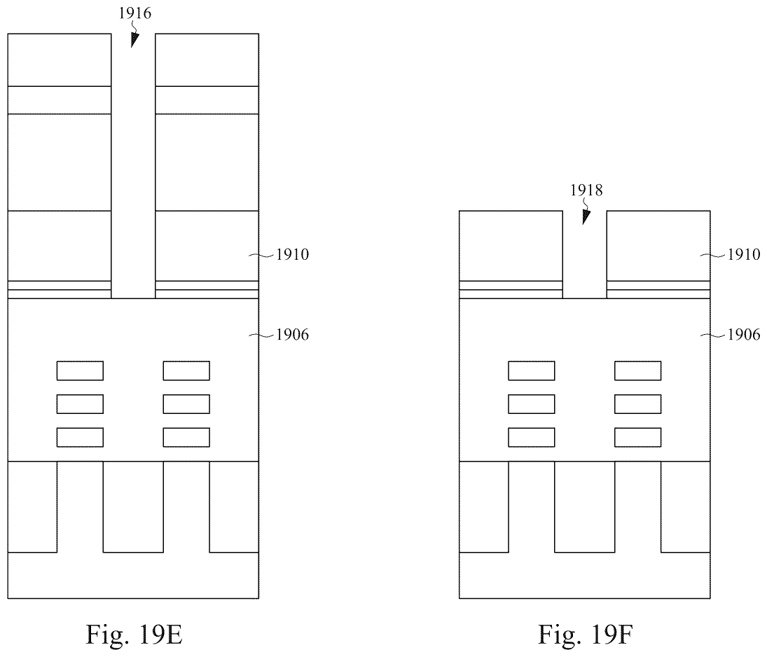

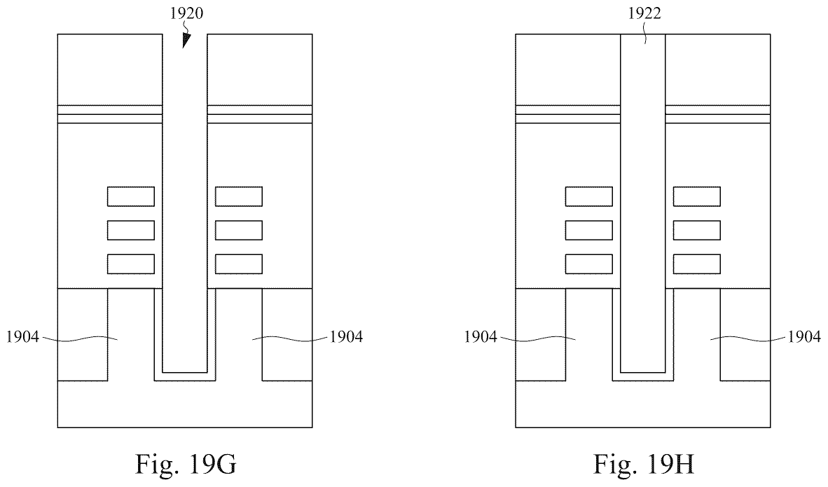

FIG. 18 is a flow chart of an example cut metal gate process 1800, in accordance with some embodiments. Additional fabrication operations may be performed between the various operations of process 1800 and may be omitted merely for clarity and ease of description. These various operations are within the spirit and the scope of this disclosure. Moreover, not all operations may be required to perform the disclosure provided herein. Additionally, some of the operations may be performed simultaneously, or in a different order than the ones shown in FIG. 18. Accordingly, it is understood that additional processes can be provided before, during, and/or after process 1800, and that some other processes may only be briefly described herein. For illustrative purposes, process 1800 will be described with reference to the embodiments shown in FIGS. 19A-19H , wherein FIGS. 19A-19H illustrates example stages of an example cut (e.g., dense cut or isolation cut) during performance of the various operations of FIG. 1800. The figures provided to describe process 1800 are for illustrative purposes only and are not to scale. In addition, the figures may not reflect the actual geometry of the actual structures, features, or films. Some structures, films, or geometries may have been deliberately augmented for illustrative purposes.

The example process 1800 starts at block 1810, with a substrate containing a first plurality of fins of a first polarity type that extend vertically above the substrate, a second plurality of fins of a second polarity type that extend vertically above the substrate, and a contiguous gate structure that extends over each of the first plurality of fins and second plurality of fins. Referring the example of FIG. 19A, in an embodiment of block 1810, a substrate 1902 containing a first plurality of fins 1904 that extend vertically above the substrate, a second plurality of fins of a second polarity type (not shown) that extend vertically above the substrate, and a contiguous gate structure 1906 that extends over each of the first plurality of fins and second plurality of fins. shallow trench isolation (STI) material 1908 is disposed between the first plurality of fins and between the second plurality of fins.

At block 1820, the example process 1800 includes forming a dielectric layer over the gate structure, which can function as a hard mask during cut metal gate operations. The dielectric layer may be formed by deposition operations. Referring to the example of FIG. 19B, in an embodiment of block 1820, a dielectric layer 1910 is formed over the contiguous gate structure 1906.

At block 1830, the example process 1800 includes forming a photolithography layer over the dielectric layer. The photolithography layer may be formed by deposition operations. Referring to the example of FIG. 19C, in an embodiment of block 1830, a photolithography layer 1912 comprising a top layer 1912a, a middle layer 1912b, and a lower layer 1912c are formed over the dielectric layer 1910.

At block 1840, the example process 1800 includes patterning the top layer of the photolithography layer. Referring to the example of FIG. 19D, in an embodiment of block 1840, the top layer 1912a of the photolithography layer 1912 is patterned to form an opening 1914 between two transistors of the same polarity type (e.g., two p-channel transistors and/or two n-channel transistors).

At block 1850, the example process 1800 includes patterning the dielectric layer. In various embodiments, the dielectric layer is patterned by etching the middle and lower layers of the photolithography to extend the opening in the top layer toward the dielectric layer and patterning the dielectric layer by further extending the opening through the dielectric layer. In various embodiments, the dielectric layer formed above and around the contiguous gate structure is patterned to form a first recess between the first pair of fins of the first polarity type and a second recess between the second pair of fins of the second polarity type. Referring to the example of FIG. 19E, in an embodiment of block 1850, a first recess 1916 is formed in the dielectric layer 1910 and the photolithography layer 1912 between a first pair of fins of the first polarity type and a second recess (not shown) is formed in the dielectric layer 1910 and the photolithography layer 1912 between a second pair of fins of the second polarity type.

At block 1860, the example process 1800 includes removing the photolithography layer. Referring to the example of FIG. 19F, in an embodiment of block 1860, the photolithography layer 1912 illustrated in FIG. 19E has been removed leaving the dielectric layer 1910 with a second opening 1918 in the dielectric layer 1910 above the contiguous gate structure 1906. Various etching techniques may be employed to remove the photolithography layer 1912.

At block 1870, the example process 1800 includes cutting the metal gate. In various embodiments, the metal gate is cut via an etching process (e.g., in a plasma dry etch chamber). In various embodiments, cutting the metal gate comprises performing a first cut and a second cut using a common etching recipe, wherein the first cut is an isolation cut that extends across a plurality of contiguous gate structures of the first polarity type and the second cut is an isolation cut that extends across a plurality of contiguous gate structures of the second polarity type. In various embodiments, cutting the metal gate comprises performing a first cut and a second cut using a common etching recipe, wherein the first cut is a dense cut that extends across a first contiguous gate structure but does not extend across an adjacent contiguous gate structure that is parallel to the first contiguous gate structure, and the second cut is a dense cut that extends across a second contiguous gate structure but does not extend across a second adjacent contiguous gate structure that is parallel to the second contiguous gate structure. In various embodiments, cutting the metal gate comprises performing a first cut and a second cut using the same (or common) etching recipe, wherein one of the first cut and the second cut is a dense cut and the other of the first cut and the second cut is an isolation cut. In various embodiments, performing a cut using the same (or common) etching recipe comprises performing common etching operations, and in various embodiments performing common etching operations comprises applying a gas source that includes a carbon passivation gas comprising CH₄ to cut a first trench and a second trench

In various embodiments, cutting the metal gate results in a polymer layer forming on sidewalls of an opening in the contiguous gate structure formed by a cut between two n-type transistors but not on sidewalls of an opening in the contiguous gate structure formed by a cut between two p-type transistors during common etching operations. The lack of polymer forming on sidewalls allows trenches formed by cuts between p-type transistors to have a larger MCD (middle CD) than an MCD of trenches formed by cuts between n-type transistors. In various embodiments, the MCD of trenches formed by cuts between p-type transistors is approximately 1.15 times to approximately 1.2 times (e.g., greater than 10%) larger than the MCD of trenches formed by cuts between n-type transistors. In various embodiments, the MCD of trenches formed by cuts between p-type transistors is approximately 21.5 nm and the MCD of trenches formed by cuts between p-type transistors is approximately 18 nm.

In various embodiments, cutting the contiguous metal gate to form a first trench between a first pair of fins of a first polarity type and a second trench between a second pair of fins of a second polarity type comprises forming the first trench through the contiguous gate structure and the STI material between the first pair of fins of the first polarity type and forming the second trench through the contiguous gate structure and the STI material between the second pair of fins of the second polarity type.

Referring to the example of FIG. 19G, in an embodiment of block 1870, a first trench 1920 between a first pair of fins 1904 of a first polarity type is provided and a second trench (not shown) is provided between a second pair of fins of a second polarity type.

At block 1880, the example process 1800 includes filling the trench with dielectric material. In various embodiments, depositing dielectric material in the first trench and the second trench isolates one of the first pair of fins from the other of the first pair of fins and isolates one of the second pair of fins from the other of the second pair of fins. Referring to the example of FIG. 19H, in an embodiment of block 1880, a dielectric layer 1922 is formed in a trench between a first fin 1904 and a second fin 1904 of a pair of transistors of the same polarity type.

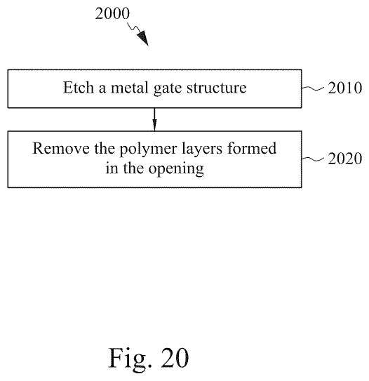

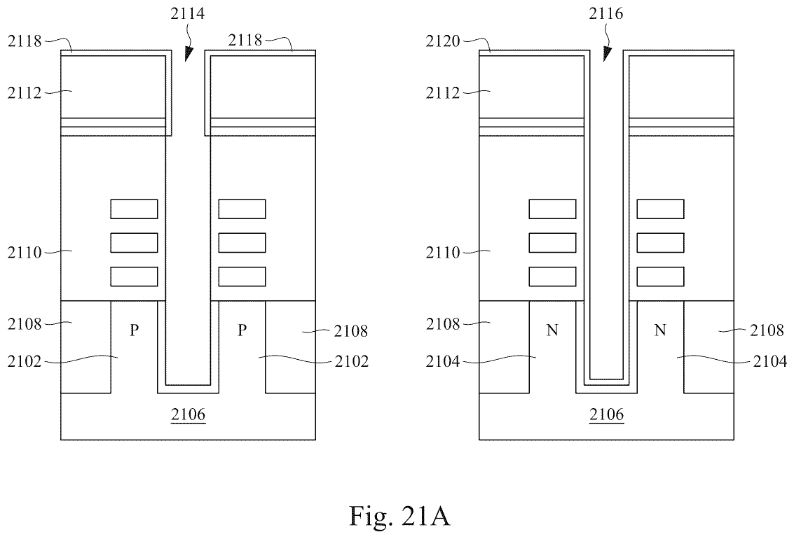

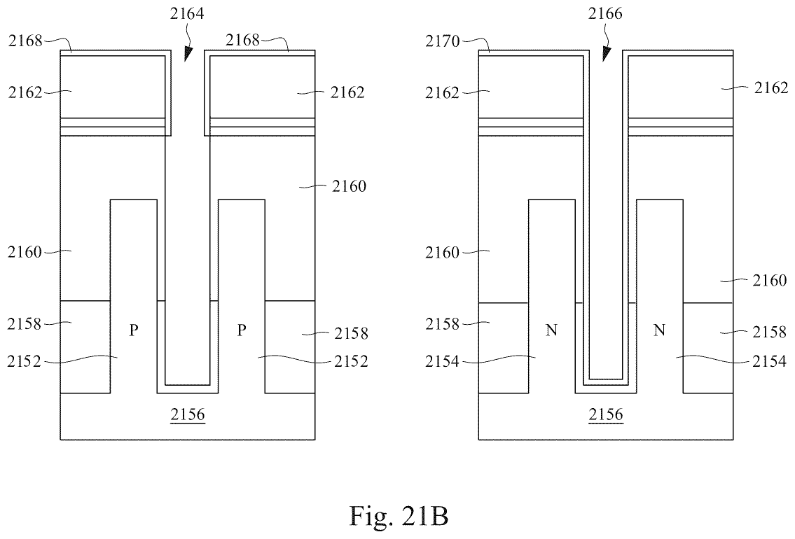

FIG. 20 is a flow diagram depicting an example method 2000 of forming a trench in a metal gate, according to some embodiments. For illustrative purposes, the operations illustrated in FIG. 20 will be described with reference to FIGS. 21A and 21B, which show cross-sectional views of a semiconductor device after etching, according to some embodiments.

The etching operations include, at operation 2010, etching a metal gate structure. In various embodiments, an opening is formed via etching in a plasma dry etch chamber using a gas source comprising an etch gas, a passivation gas, and a dilute gas to cut or etch a trench or opening in a gate structure between transistors. An ILD structure may be employed as an etch mask (or hard mask) in the plasma dry etch chamber and an opening in the ILD structure defines the location of the trench. Surfaces of gate structure are etched in the plasma dry etch chamber to produce the trench.

In various embodiments, the etching is accomplished using a gas source comprising an etch gas (e.g., Cl₂/HBr/CF₄/CHF₃/CH₂F₂/CH₃F/C₄F₆/BCl₃/SF₆/H₂/NF₃), a Carbon passivation gas comprising CH₄, and a dilute gas (e.g., He). In various embodiments, the etch gas is administered with a chamber pressure of approximately 5 mT, at a source power from about 0 -1000 W, at a 50-100% duty cycle, and a frequency of 10-1000 Hz. In various embodiments, the Carbon passivation gas comprises CH₄ administered at approximately 25 -125 sccm (standard cubic centimeters per minute), and the dilute gas comprises He administered at approximately 100-500 sccm.

Carbon passivation selectively deposits on N-metal rather than P metal due to N/P work function material differences (e.g., presence of Al as a work function metal for n-metal gates but not for p-metal gates), which results in P site CD enlargement. In various embodiments, during the etching, the passivation gas controls the rate of polymer formation. For cutting a gate structure between a pair of p-channel transistors, no polymer is formed on sidewalls of the cut in the gate structure as illustrated in FIGS. 21A-21B. For cutting a gate structure between a pair of n-channel transistors, some polymer is formed on sidewalls of the cut in the gate structure also as illustrated in FIGS. 21A-21B. The lack of polymer forming on the sidewalls of the cut in the gate structure between two p-channel transistors allows the MCD of the cut in the gate structure between two p-channel transistors to be larger than the MCD of a cut in the gate structure between two n-channel transistors.

Since a gate structure is actually an electrode buried in one or more dielectric materials, it may form a parasitic capacitor with the active region of the transistor, which may create unwanted parasitic and fringe capacitance in the integrated circuit. In addition to parasitic capacitance near the gate structure, fringe capacitance slows down the ring oscillator speed of the integrated circuit and negatively impacts the threshold voltage of the transistor. The larger MCD causes the gate-to-contact capacitance to become decreased, leading to lower parasitic capacitance for ring oscillator speed boost and better device performance, such as decrease power consumption. In various embodiments the gate effective capacitance can be reduced by about 3%-10%.

FIG. 21A is a cross-section diagram of an example semiconductor structure with a pair of p-channel fins 2102 for a GAAFET and a pair of n-channel fins 2104 for a GAAFET formed above a substrate 2106. STI 2108 is formed between the fins and a metal gate structure 2110 is formed above the STI 2108. A dielectric layer 2112 is formed above the metal gate structure 2110. A first trench 2114 is formed between the first pair of p-channel fins 2102, and a second trench 2116 is formed between the second pair of n-channel fins 2104. A first polymer layer 2118 is formed on sidewalls of the first trench 2114 in the region of the dielectric layer 2112, but not on sidewalls in the regions of the metal gate structure 2110 and the STI 2108. A second polymer layer 2120 is formed on sidewall of the second trench 2116 in regions of the dielectric layer 2112, the metal gate structure 2110, and the STI 2108.

FIG. 21B is a cross-section diagram of an example semiconductor structure with a pair of p-channel fins 2152 for a FinFET and a pair of n-channel fins 2154 for a FinFET formed above a substrate 2156. STI 2158 is formed between the fins and a metal gate structure 2160 is formed above the STI 2158. A dielectric layer 2162 is formed above the metal gate structure 2160. A first trench 2164 is formed between the first pair of p-channel fins 2152, and a second trench 2166 is formed between the second pair of n-channel fins 2154. A first polymer layer 2168 is formed on sidewalls of the first trench 2164 in the region of the dielectric layer 2162, but not on sidewalls in the regions of the metal gate structure 2160 and the STI 2158. A second polymer layer 2170 is formed on sidewall of the second trench 2166 in regions of the dielectric layer 2162, the metal gate structure 2160, and the STI 2158.

After formation of the opening, the example method 2000 at operation 2020 includes removing the polymer layers formed in the opening. The polymer layers (e.g., first polymer layer 2118, second polymer layer 2120, first polymer layer 2168, and second polymer layer 2170) may be removed by methods, such as, for example, wet strip or plasma ashing operations. These procedures are well-known by those skilled in the art and widely practiced.

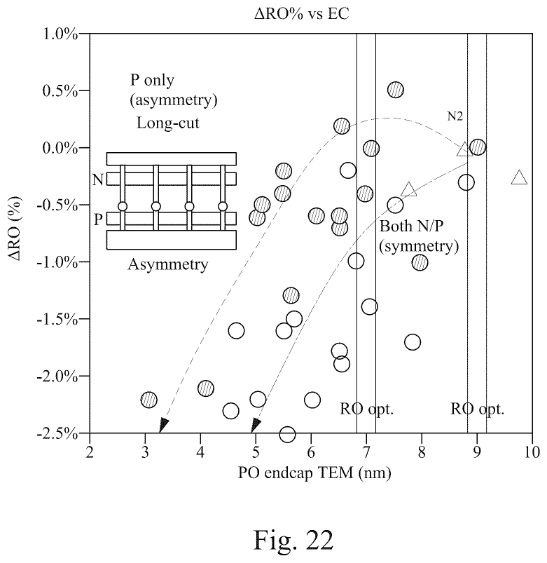

FIG. 22 is a graph of change in ring oscillator speed percentage vs. end cap length. FIG. 22 illustrates that when the end cap length for N-channel FinFETs and P-channel FinFETs are approximately the same (e.g., less than 5% difference), the ring oscillator speed of the transistor devices increase. FIG. 22 also illustrates that when the end cap length for P-channel FinFETs and N-channel FinFETs are not the same (e.g., greater than 10% difference), the ring oscillator speed of the p-channel transistor devices increase with the length of the end cap to a point (e.g. 7 nm) and then begins to decrease past the point. The maximum ring oscillator speed of the p-channel transistor devices at that point is greater than the maximum ring oscillator speed of the transistor devices when the end cap length for N-channel FinFETs and P-channel FinFETs are approximately the same.

In some aspects, the techniques described herein relate to a method including: providing a substrate containing a first plurality of fins of a first polarity type that extend vertically above the substrate, a second plurality of fins of a second polarity type that extend vertically above the substrate, and a contiguous gate structure that extends over each of the first plurality of fins and second plurality of fins; and forming a first opening in the contiguous gate structure with a first cut between the first pair of fins of the first polarity type and a second opening in the contiguous gate structure with a second cut between the second pair of fins of the second polarity type via common etching operations; wherein the first opening has a first middle critical dimension (MCD) and the second opening has a second MCD and wherein one of the first MCD and the second MCD is larger than the other of the first MCD and the second MCD; wherein the common etching operations includes applying a gas source that includes a carbon passivation gas including CH4 to cut the first opening and the second opening.

In some aspects, the techniques described herein relate to a method, wherein the larger of the first MCD and the second MCD is more than 10% larger than the smaller of the first MCD and the second MCD.

In some aspects, the techniques described herein relate to a method, wherein the larger of the first MCD and the second MCD is approximately 1.15 times to approximately 1.2 times larger than the smaller of the first MCD and the second MCD.

In some aspects, the techniques described herein relate to a method, wherein a polymer layer forms on sidewalls of the second opening in the contiguous gate structure but not on sidewalls of the first opening in the contiguous gate structure during the common etching operations.

In some aspects, the techniques described herein relate to a method, wherein forming the first opening and the second opening includes: patterning a dielectric structure formed above and around the contiguous gate structure to form a first recess between the first pair of fins of the first polarity type and a second recess between the second pair of fins of the second polarity type; and forming the first opening underneath the first recess and the second opening underneath the second recess.

In some aspects, the techniques described herein relate to a method, wherein shallow trench isolation (STI) material is disposed between the first plurality of fins and the second plurality of fins and forming the first opening and the second opening includes forming the first opening through the contiguous gate structure and into the STI material between the first pair of fins of the first polarity type and forming the second opening through the contiguous gate structure and into the STI material between the second pair of fins of the second polarity type.

In some aspects, the techniques described herein relate to a method, wherein the first cut extends across a plurality of contiguous gate structures of the first polarity type and the second cut extends across a plurality of contiguous gate structures of the second polarity type.

In some aspects, the techniques described herein relate to a method, wherein the first cut extends across a first contiguous gate structure but does not extend across an adjacent contiguous gate structure that is parallel to the first contiguous gate structure and the second cut extends across a second contiguous gate structure but does not extend across a second adjacent contiguous gate structure that is parallel to the second contiguous gate structure.

In some aspects, the techniques described herein relate to a method, further including depositing dielectric material in the first opening and the second opening isolating one of the first pair of fins from the other of the first pair of fins and isolating one of the second pair of fins from the other of the second pair of fins.

In some aspects, the techniques described herein relate to a semiconductor structure including: a substrate including a first plurality of fins of a first polarity type that extend vertically above the substrate, a second plurality of fins of a second polarity type that extend vertically above the substrate, and a gate structure that extends over the first plurality of fins and second plurality of fins; and a first opening in the gate structure filled with dielectric material between the first pair of fins of the first polarity type and a second opening in the gate structure filled with the dielectric material between the second pair of fins of the second polarity type; wherein the first opening has a first middle critical dimension (MCD) and the second opening has a second MCD and wherein one of the first MCD and the second MCD is larger than the other of the first MCD and the second MCD.

In some aspects, the techniques described herein relate to a semiconductor structure, wherein the larger of the first MCD and the second MCD is more than 10% larger than the smaller of the first MCD and the second MCD.

In some aspects, the techniques described herein relate to a semiconductor structure, wherein the larger of the first MCD and the second MCD is approximately 1.15 times to approximately 1.2 times larger than the smaller of the first MCD and the second MCD.

In some aspects, the techniques described herein relate to a semiconductor structure, wherein the larger of the first MCD and the second MCD is approximately 18 nanometers (nm) and the smaller of the first MCD and the second MCD is approximately 21.5 nm.

In some aspects, the techniques described herein relate to a semiconductor structure, further including a first cut that separates a plurality of gate structures of the first polarity type into a first plurality of separate gate sections and a second cut that separates a plurality of gate structures of the second polarity type into a second plurality of separate gate sections.

In some aspects, the techniques described herein relate to a semiconductor structure, further including a first cut that separates a gate structure of the first polarity type into two separate gate sections wherein the first cut extends across a first gate structure of the first polarity type but does not extend across an adjacent gate structure of the first polarity type that is parallel to the first gate structure of the first polarity type and a second cut that separates a gate structure of the second polarity type into two separate gate sections wherein the second cut extends across a first gate structure of the second polarity type but does not extend across an adjacent gate structure of the second polarity type that is parallel to the first gate structure of the second polarity type.

In some aspects, the techniques described herein relate to a semiconductor structure, wherein the gate structure includes a polysilicon (PO) structure.

In some aspects, the techniques described herein relate to a semiconductor structure, wherein the gate structure includes a gate structure for a gate all around device.

In some aspects, the techniques described herein relate to a semiconductor structure, wherein the gate structure includes a gate structure for a FinFET device.

In some aspects, the techniques described herein relate to a method including: providing a substrate containing a first plurality of fins of a first polarity type, a second plurality of fins of a second polarity type, and a contiguous gate structure that extends over each of the first plurality of fins and second plurality of fins; and forming a first opening in the contiguous gate structure with a first cut between the first pair of fins of the first polarity type and a second opening in the contiguous gate structure with a second cut between the second pair of fins of the second polarity type via common etching operations; wherein performing the common etching operations includes forming the first opening with a first middle critical dimension (MCD) and the second opening with a second MCD, wherein the first MCD is larger than the second MCD.

In some aspects, the techniques described herein relate to a method, wherein performing the common etching operations further includes forming a polymer layer on sidewalls of the second opening in the contiguous gate structure without forming a polymer layer on sidewalls of the first opening in the contiguous gate structure.

In some aspects, the techniques described herein relate to a method, wherein performing the common etching operations further includes etching the contiguous gate structure using a carbon passivation gas including CH4 administered at approximately 25 -125 sccm (standard cubic centimeters per minute).

In some aspects, the techniques described herein relate to a method, wherein the first cut extends across a first contiguous gate structure but does not extend across an adjacent contiguous gate structure that is parallel to the first contiguous gate structure and the second cut extends across a second contiguous gate structure but does not extend across a second adjacent contiguous gate structure that is parallel to the second contiguous gate structure.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method comprising:
providing a substrate containing a first plurality of fins of a first polarity type that extend vertically above the substrate, a second plurality of fins of a second polarity type that extend vertically above the substrate, and a contiguous gate structure that extends over each of the first plurality of fins and second plurality of fins;
forming a first opening in the contiguous gate structure with a first cut between a first pair of fins of the first polarity type and a second opening in the contiguous gate structure with a second cut between a second pair of fins of the second polarity type via common etching operations; and
wherein the first opening has a first middle critical dimension (MCD) and the second opening has a second MCD and wherein one of the first MCD and the second MCD is larger than a second of the first MCD and the second MCD;
wherein the common etching operations comprises applying a gas source that includes a carbon passivation gas comprising CH₄ to cut the first opening and the second opening.

2. The method of claim 1, wherein the larger of the first MCD and the second MCD is more than 10% larger than a smaller of the first MCD and the second MCD.

3. The method of claim 1, wherein a polymer layer forms on sidewalls of the second opening in the contiguous gate structure but not on sidewalls of the first opening in the contiguous gate structure during the common etching operations.

4. The method of claim 1, wherein forming the first opening and the second opening comprises:
patterning a dielectric structure formed above and around the contiguous gate structure to form a first recess between the first pair of fins of the first polarity type and a second recess between the second pair of fins of the second polarity type; and
forming the first opening underneath the first recess and the second opening underneath the second recess.

5. The method of claim 1, wherein shallow trench isolation (STI) material is disposed between the first plurality of fins and the second plurality of fins and forming the first opening and the second opening comprises forming the first opening through the contiguous gate structure and into the STI material between the first pair of fins of the first polarity type and forming the second opening through the contiguous gate structure and into the STI material between the second pair of fins of the second polarity type.

6. The method of claim 1, wherein the first cut extends across a plurality of contiguous gate structures of the first polarity type and the second cut extends across a plurality of contiguous gate structures of the second polarity type.

7. The method of claim 1, wherein the first cut extends across a first contiguous gate structure but does not extend across an adjacent contiguous gate structure that is parallel to the first contiguous gate structure and the second cut extends across a second contiguous gate structure but does not extend across a second adjacent contiguous gate structure that is parallel to the second contiguous gate structure.

8. The method of claim 1, further comprising depositing dielectric material in the first opening and the second opening isolating one of the first pair of fins from a second of the first pair of fins and isolating one of the second pair of fins from a second of the second pair of fins.

9. A semiconductor structure comprising:
a substrate comprising a first plurality of fins of a first polarity type that extend vertically above the substrate, a second plurality of fins of a second polarity type that extend vertically above the substrate, and a gate structure that extends over the first plurality of fins and second plurality of fins; and
a first opening in the gate structure filled with dielectric material between a first pair of fins of the first polarity type and a second opening in the gate structure filled with the dielectric material between a second pair of fins of the second polarity type;
wherein the first opening has a first middle critical dimension (MCD) and the second opening has a second MCD and wherein one of the first MCD and the second MCD is larger than a second of the first MCD and the second MCD.

10. The semiconductor structure of claim 9, wherein the larger of the first MCD and the second MCD is approximately 1.15 times to approximately 1.2 times larger than a smaller of the first MCD and the second MCD.

11. The semiconductor structure of claim 9, wherein the larger of the first MCD and the second MCD is approximately 18 nanometers (nm) and a smaller of the first MCD and the second MCD is approximately 21.5 nm.

12. The semiconductor structure of claim 9, further comprising a first cut that separates a plurality of gate structures of the first polarity type into a first plurality of separate gate sections and a second cut that separates a plurality of gate structures of the second polarity type into a second plurality of separate gate sections.

13. The semiconductor structure of claim 9, further comprising a first cut that separates a gate structure of the first polarity type into two separate gate sections wherein the first cut extends across a first gate structure of the first polarity type but does not extend across an adjacent gate structure of the first polarity type that is parallel to the first gate structure of the first polarity type and a second cut that separates a gate structure of the second polarity type into two separate gate sections wherein the second cut extends across a first gate structure of the second polarity type but does not extend across an adjacent gate structure of the second polarity type that is parallel to the first gate structure of the second polarity type.

14. The semiconductor structure of claim 9, wherein the gate structure comprises a polysilicon (PO) structure.

15. The semiconductor structure of claim 9, wherein the gate structure comprises a gate structure for a gate all around device.

16. The semiconductor structure of claim 9, wherein the gate structure comprises a gate structure for a FinFET device.

17. A method comprising:
providing a substrate containing a first plurality of fins of a first polarity type, a second plurality of fins of a second polarity type, and a contiguous gate structure that extends over each of the first plurality of fins and second plurality of fins; and
forming a first opening in the contiguous gate structure with a first cut between a first pair of fins of the first polarity type and a second opening in the contiguous gate structure with a second cut between a second pair of fins of the second polarity type via common etching operations;
wherein performing the common etching operations comprises forming the first opening with a first middle critical dimension (MCD) and the second opening with a second MCD, wherein the first MCD is larger than the second MCD.

18. The method of claim 17, wherein performing the common etching operations further comprises forming a polymer layer on sidewalls of the second opening in the contiguous gate structure without forming a polymer layer on sidewalls of the first opening in the contiguous gate structure.

19. The method of claim 17, wherein performing the common etching operations further comprises etching the contiguous gate structure using a carbon passivation gas comprising CH₄ administered at approximately 25 -125 sccm (standard cubic centimeters per minute).

20. The method of claim 17, wherein the first cut extends across a first contiguous gate structure but does not extend across an adjacent contiguous gate structure that is parallel to the first contiguous gate structure and the second cut extends across a second contiguous gate structure but does not extend across a second adjacent contiguous gate structure that is parallel to the second contiguous gate structure.
